(19) United States
(12) Patent Application Publication
(10) Pub. No.: US 2025/0364198 A1
(43) Pub. Date: Nov. 27, 2025

(54) ELECTROMECHANICAL SWITCH AND METHOD FOR MANUFACTURING THE SAME

(71) Applicant: Korea Advanced Institute of Science And Technology, Daejeon (KR)

(72) Inventors: Jun-Bo YOON, Daejeon (KR); Soyoung LEE, Daejeon (KR); Taesoo KIM, Daejeon (KR)

(73) Assignee: Korea Advanced Institute of Science And Technology, Daejeon (KR)

(21) Appl. No.: 19/213,444

(22) Filed: May 20, 2025

(30) Foreign Application Priority Data
May 21, 2024 (KR) 10-2024-0065509

(51) Int. Cl. H01H 59/00; B81B 3/00; B81C 1/00; H01H 49/00

(52) U.S. Cl. CPC H01H 59/0009; B81B 3/0081; B81C 1/00373; H01H 49/00; B81B 2201/018; B81B 2203/04; B81C 2201/0176; B81C 2201/0181

(57) ABSTRACT

The present invention relates to an electromechanical switch and a method for manufacturing the same, and more particularly, to a superconducting contact electromechanical switch that reliably operates at an ultra-low temperature (10 to 100 mK) and has low on-state resistance and a method for manufacturing the same.

An electromechanical switch according to an embodiment of the present invention includes: a substrate; a first electrode disposed on the substrate; a second electrode disposed on the substrate; a third electrode disposed on the substrate; and a switch body disposed at a central point surrounded by the first to third electrodes on the substrate. Here, each of the second and third electrodes is spaced a predetermined distance from the first electrode.

### CROSS-REFERENCE TO RELATED APPLICATIONS

This US non-provisional patent application claims priority under 35 USC § 119 of Korean Patent Application No. 10-2024-0065509, filed on May 21, 2024, the entire contents of which are hereby incorporated by reference.

### BACKGROUND

The present invention relates to an electromechanical switch and a method for manufacturing the same, and more particularly, to a superconducting contact electromechanical switch that reliably operates at an ultra-low temperature (10 to 100 mK) and has low on-state resistance and a method for manufacturing the same.

A micro/nano electromechanical switch (M/NEM switch) is an element that abruptly switches current and voltage through mechanical contact between metals with an air-gap therebetween.

Since the electromechanical switch performs on/off switching through a mechanical movement, the mechanical switch has an advantage of exhibiting minimal performance degradation under extreme environment, such as a high temperature or an extremely low temperature, in comparison with a semiconductor element.

A quantum computing field that is recently recognized as a next-generation industrial field requires a switch capable of operating reliably under an environment with extremely low temperatures (10 to 100 mK) in which a qubit operates and processing a radio frequency (RF) signal.

The electromechanical switch has an advantage of robust in a harsh environment, which satisfies requirements of quantum computing fields. Thus, various researches on the electromechanical switch are being performed.

Also, since the electromechanical switch has linearity and power handling characteristics greater than other RF switches, such as PIN and CMOS, the electromechanical switch exhibits an excellent performance as a RF switch.

An RF switch having a low on resistance to process an RF signal while operating reliably in an ultra-low temperature (10 to 100 mK) is required to be applied in the field of quantum computing. However, an RF switch having both characteristics simultaneously has not been reported.

Although an electromechanical switch operates reliably at the ultra-low temperature (10 to 100 mK) for a lifetime (up to 108 cycles) is reported, the electromechanical switch is unsuitable as the RF switch due to a high on-state resistance thereof.

Also, although an electromechanical switch exhibiting a performance as the RF switch at the ultra-low temperature (10 to 100 mK) is reported, the electromechanical switch does not exhibit reliability at the same time.

### SUMMARY

The present invention provides an electromechanical switch that reliably operate at an ultra-low temperature (10 to 100 mK) and a method for manufacturing the same.

The present invention also provides an electromechanical switch having a low on-state resistance to process a radio frequency (RF) signal and a method for manufacturing the same.

The present invention also provides an electromechanical switch capable of relieving thermal stress caused by a great temperature difference from the room temperature to achieve high reliability in an ultra-low temperature (10 to 100 mK) environment and a method for manufacturing the same.

The present invention also provides an electromechanical switch capable of managing von Mises stress of a switch to be less than a reference value (yield stress/factor of safety) to secure high reliability and a method for manufacturing the same.

An embodiment of the present invention provides an electromechanical switch including: a substrate; a first electrode disposed on the substrate; a second electrode disposed on the substrate; a third electrode disposed on the substrate; and a switch body disposed at a central point surrounded by the first to third electrodes on the substrate, in which each of the second and third electrodes is spaced a predetermined distance from the first electrode.

In an embodiment, the switch body may include: a base part disposed on the central point; a first protruding part; a second protruding part; a third protruding part; and a fourth protruding part, in which the first to fourth protruding parts may be connected to four side surfaces of the base part, respectively, and symmetrically arranged.

In an embodiment, the base part may include a contact part configured to bring the second electrode into contact with the switch body, and each of the first to fourth protruding parts may include: a fixing part configured to fix the switch body onto the substrate; and a spring part that has a slot structure.

In an embodiment, the slot structure of the spring part may have a first length that is greater than a second length.

In an embodiment, an air-gap may be defined between the second electrode and the switch body.

In an embodiment, the air-gap may have a displacement in a range from −9 nm to 9.3 nm in a direction perpendicular to the substrate at a temperature of 0.01K to 300K.

In an embodiment, when a predetermined voltage is applied to the first electrode, electrostatic force may be generated between the first electrode and the switch body to bring the second electrode into contact with the switch body, and the electrostatic force may be greater than mechanical restoration force of the switch body.

In an embodiment, the electromechanical switch may have: an on state in which the second electrode is in contact with the switch body by the electrostatic force; and an off state in which the second electrode is physically spaced apart from the switch body by the air-gap.

In an embodiment, the electromechanical switch may further include an insulating layer disposed between the first electrode and the second and third electrodes.

In an embodiment, the insulating layer may include silicon nitride (Si₃N₄) and aluminum nitride (AlN).

In an embodiment, a maximum stress of the switch body may be less than 137.5 MPa at a temperature of 0.01 K to 300 K.

In an embodiment, the switch body may have a thickness greater than that of each of the first to third electrodes

In an embodiment, each of the first to third electrodes and the switch body may be made of a superconducting material.

In an embodiment, the superconducting material may be molybdenum.

In an embodiment of the present invention, a method for manufacturing an electromechanical switch includes: a first electrode formation process of forming a first electrode on a substrate; a first deposition process of depositing a first insulating layer on the substrate and the first electrode; a second deposition process of depositing a second insulating layer on a partial area of the first insulating layer; a second electrode formation process of forming a second electrode on the second insulating layer; a third electrode formation process of forming a third electrode on the second insulating layer; a third deposition process of depositing a sacrificial layer for forming a contact part and a fixing part on the second insulating layer and the first to third electrodes; a switch body formation process of forming a switch body on the sacrificial layer; and a sacrificial layer release process of releasing the sacrificial layer.

In an embodiment, each of the first to third electrodes and the switch body may be made of molybdenum.

In an embodiment, the first insulating layer may be made of silicon nitride (Si₃N₄) and deposited through plasma-enhanced chemical vapor deposition.

In an embodiment, the second insulating layer may be made of aluminum nitride (AlN) and deposited through sputtering.

In an embodiment, the sacrificial layer may be made of silicon dioxide (SiO₂) and deposited through plasma-enhanced chemical vapor deposition.

### BRIEF DESCRIPTION OF THE FIGURES

FIG. 1 is a perspective view illustrating an electromechanical switch according to an embodiment of the present invention.

FIG. 2 is a schematic view illustrating a vertical cross-sectional structure at point A of FIG. 1.

FIG. 3A is a graph illustrating results obtained by measuring superconductivity of a 100 nm thin film made of molybdenum, and FIG. 3B is an enlarged graph illustrating portion A in FIG. 3A.

FIG. 4 is a plan view illustrating a switch body included in the electromechanical switch according to an embodiment of the present invention.

FIG. 5A is an enlarged view illustrating portion A in FIG. 4, and FIG. 5B is an enlarged view illustrating portion B in FIG. 4.

FIG. 6A is a 3D image illustrating the electromechanical switch according to an embodiment of the present invention, and FIG. 6B is a graph for explaining a height variation along line A-A′ in FIG. 6A.

FIG. 7A is an SEM image of the electromechanical switch according to an embodiment of the present invention, and FIG. 7B is an FIB image of a cross-section obtained by vertically cutting a ‘FIB cut’ portion of FIG. 7A.

FIG. 8 is a view for comparing a typical electromechanical switch without the slot structure and the electromechanical switch adopting the slot structure according to an embodiment of the present invention.

FIG. 9 is a graph showing results of a simulation, which confirm that a maximum von Mises stress applied to the switch body decreases as a ratio b/a of a first length b and a second length a of the slot structure increases in an ultra-low temperature (10 mK) environment.

FIG. 10A and FIG. 10B are a view for explaining an operation principle of the electromechanical switch.

FIG. 11A and FIG. 11B are a view illustrating results of a simulation that verifies operation stability of the electromechanical switch at the ultra-low temperature according to an embodiment of the present invention.

FIG. 12A and FIG. 12B are a graph representing the results of the simulation of FIGS. 11A and 11B.

FIG. 13A, FIG. 13B and FIG. 13C are a view and a graph illustrating a result of a radio frequency (RF) simulation that verifies port impedance Zo of the electromechanical switch according to an embodiment of the present invention.

FIG. 14A and FIG. 14B are a graph illustrating a result of a RF simulation that extracts a S-parameter of the electromechanical switch according to an embodiment of the present invention.

FIG. 15A and FIG. 15B are a graph representing a result obtained by measuring current-voltage characteristics at a temperature of 4.8 K of the electromechanical switch according to an embodiment of the present invention.

FIG. 16A and FIG. 16B are a graph representing a result obtained by measuring, at a temperature of 4.8K, a switching time of the electromechanical switch according to an embodiment of the present invention.

FIG. 17A and FIG. 17B are a graph representing a result obtained by measuring, at a temperature of 4.8K, a lifetime of the electromechanical switch according to an embodiment of the present invention.

FIG. 18 is a flowchart illustrating a method for manufacturing an electromechanical switch 100 in FIG. 1.

FIG. 19 is a view for entire processes of the method for manufacturing the electromechanical switch 100 in FIG. 1.

FIG. 20A is a view for explaining a first electrode formation process S100 in FIG. 19.

FIG. 20B is a view for explaining a first deposition process S200 in in FIG. 19.

FIG. 20C is a view for explaining a second deposition process S300 in FIG. 19.

FIG. 20D is a view for explaining a second electrode formation process S400 and a third electrode formation process S500 in FIG. 19.

FIG. 20E is a view for explaining a formation of a contact part in a third deposition process S600 in FIG. 19.

FIG. 20F is a view for explaining a formation of a fixing part in the third deposition process S600 in FIG. 19.

FIG. 20G is a view for explaining a switch body formation process S700 in FIG. 19.

FIG. 20H is a view for explaining a sacrificial layer release process S800 in FIG. 19.

### DETAILED DESCRIPTION

Hereinafter, preferred embodiments of the present invention will be described in detail with reference to the accompanying drawings. It will be understood that the same reference numerals designate the same components throughout the drawings. For reference, detailed descriptions related to well-known functions or configurations will be ruled out in order not to unnecessarily obscure subject matters of the present invention.

Hereinafter, an electromechanical switch and a method for manufacturing the same will be described in detail with reference to the accompanying drawings.

### Basic Structure of Electromechanical Switch

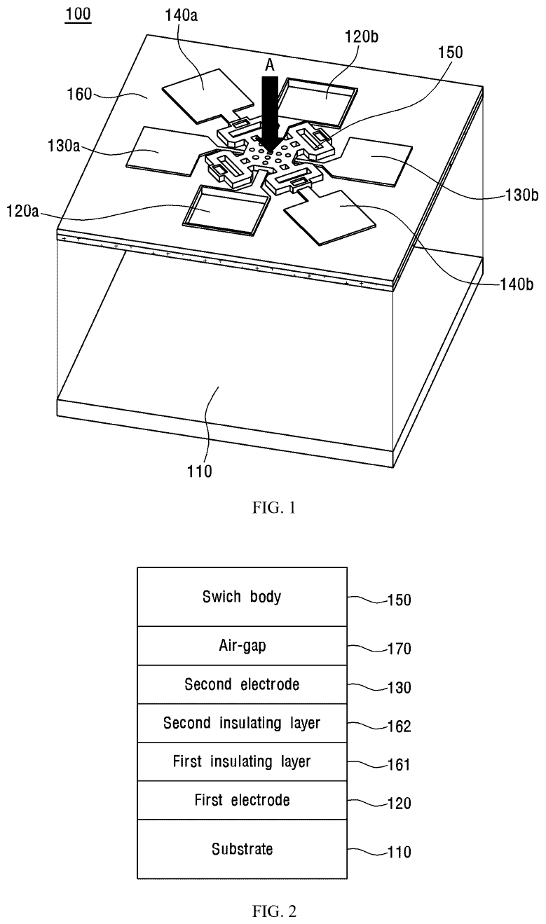

FIG. 1 is a perspective view of an electromechanical switch according to an embodiment of the present invention, and FIG. 2 is a schematic view illustrating a vertical cross-sectional structure at point A of FIG. 1.

Referring to FIGS. 1 and 2, an electromechanical switch 100 according to an embodiment of the present invention includes a substrate 110, a first electrode 120, a second electrode 130, a third electrode 140, a switch body 150, an insulating layer 160, and an air-gap 170.

The first electrode 120 may be made of molybdenum that is a superconducting material and referred to as a gate electrode.

The first electrode 120 may be disposed on the substrate 110 and have a predetermined thickness. Although the first electrode 120 may include rectangular flat electrodes 120a and 120b disposed at both ends thereof, the embodiment of the present invention is not limited thereto. For example, the first electrode 120 may include an electrode having a different shape or a non-flat electrode. The electrodes 120a and 120b disposed at both the ends may be connected through a connection part (not shown) and integrated with each other.

The second electrode 130 may be made of molybdenum that is a superconducting material and referred to as a drain electrode.

The second electrode 130 may be disposed on the substrate 110 and have a predetermined thickness. Although the second electrode 130 may include rectangular flat electrodes 130a and 130b disposed at both ends thereof, the embodiment of the present invention is not limited thereto. For example, the second electrode 130 may include an electrode having a different shape or a non-flat electrode. The electrodes 130a and 130b disposed at both the ends may be connected through a connection part (not shown) and integrated with each other.

The third electrode 140 may be made of molybdenum that is a superconducting material and referred to as a source electrode.

The third electrode 140 may be disposed on the substrate 110 and have a predetermined thickness. Although the third electrode 140 may include rectangular flat electrodes 140a and 140b disposed at both ends thereof, the embodiment of the present invention is not limited thereto. For example, the third electrode 140 may include an electrode having a different shape or a non-flat electrode. The electrodes 140a and 140b disposed at both the ends may be connected through a connection part (not shown) and integrated with each other.

Each of the second electrode 130 and the third electrode 140 may be spaced a predetermined distance from the first electrode 120 and disposed at a position higher than the first electrode 120. Also, the second electrode 130 and the third electrode 140 may be disposed on the same plane.

The insulating layer 160 may be disposed between the first electrode 120 and the second and third electrodes 130 and 140 on the substrate and have a predetermined thickness. Thus, the insulating layer 160 may electrically insulate the first electrode 120 from the second and third electrodes 130 and 140.

The insulating layer 160 includes a first insulating layer 161 and a second insulating layer 162. The second insulating layer 162 may be disposed on the first insulating layer 161 and have a thickness greater than that of the first insulating layer 161. The first insulating layer 161 may be made of silicon nitride (Si₃N₄), and the second insulating layer 162 may be made of aluminum nitride (AlN).

The switch body 150 may be made of molybdenum that is a superconducting material and referred to as a source structure.

The switch body 150 may be disposed at a central point surrounded by the first electrode 120, the second electrode 130, and the third electrode 140 on the substrate 110 and have a predetermined thickness. However, the switch body 150 may have a thickness greater than that of each of the first electrode 120, the second electrode 130, and the third electrode 140.

The switch body 150 may be disposed at a position higher than the second electrode 130 and the third electrode 140, and a portion of the switch body 150 may be in contact with the electrodes 140a and 140b disposed at both the ends of the third electrode 140. At the same time, the rest portion of the switch body 150 may not be in contact with any component.

The electromechanical switch 100 according to an embodiment of the present invention may secure reliability at ultra-low temperatures (10 to 100 mK) by designing a thermal stress of the switch body 150 to be lower than allowable stress of a material of the switch body 150.

Thus, the switch body 150 may be designed to have a structure of relieving thermal stress, and a displacement may occur in at least a portion thereof in accordance with temperature variations. More specifically, the switch body 150 is designed to receive a maximum von Mises stress below allowable stress of molybdenum in a temperature range from 0.01 K to 300 K.

The allowable stress of molybdenum is obtained by dividing yield stress of molybdenum by a factor of safety based on Mathematical equation 1 below. When molybdenum in a thin-film state has yield stress of 550 MPa, and an arbitrary factor of safety is set to 4 to ensure reliability of the electromechanical switch 100 according to an embodiment of the present invention, the allowable stress of molybdenum may be calculated as 137.5 MPa.

Allowable stress(σ_{allow})=Yield stress(σ_{Yield})/Factor of Safety [Mathematical equation 1]

Thus, the switch body 150 may be designed to receive a maximum von Mises stress less than 137.5 MPa in the temperature range from 0.01 K to 300 K. The structure of the switch body 150 will be described in detail below.

An empty space may exist between the switch body 150 and the second electrode 130, and the empty space may be referred to as the air-gap 170. The second electrode 130 and the switch body 150 may be physically spaced apart from each other by the air-gap 170. An operating method of the electromechanical switch will be described in detail below.

Each of the first to third electrodes 120, 130, and 140 and the switch body 150 may be made of a superconducting material. For example, each of the first to third electrodes 120, 130, and 140 and the switch body 150 may be made of molybdenum.

The electromechanical switch 100 according to an embodiment of the present invention may achieve a low insertion loss in an ultra-low temperature (10 to 100 mK) environment by using the molybdenum having a superconducting property, Also, since the electromechanical switch 100 has a low on-resistance, the electromechanical switch 100 may be used as a radio frequency (RF) switch to process a RF signal.

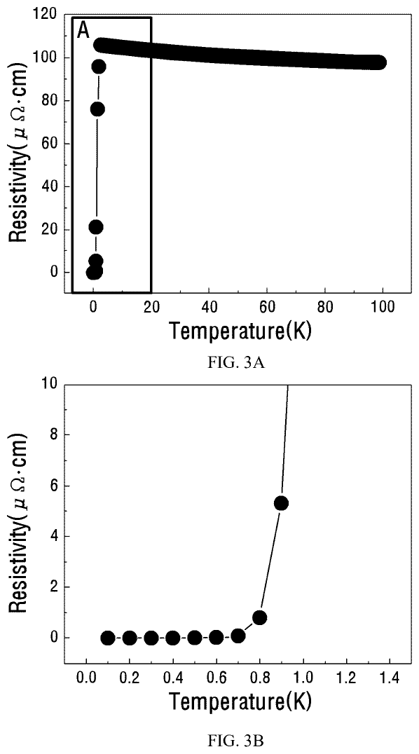

FIG. 3A is a graph illustrating results obtained by measuring superconductivity of a 100 nm thin film made of molybdenum, and FIG. 3B is an enlarged graph illustrating portion A in FIG. 3A.

Referring to FIG. 3, it may be known that the 100 nm thin film made of molybdenum exhibits superconductivity because the 100 nm thin film has zero resistance at a temperature of about 0.8K or less.

### Thermal Stress Relieving Structure of Switch Body

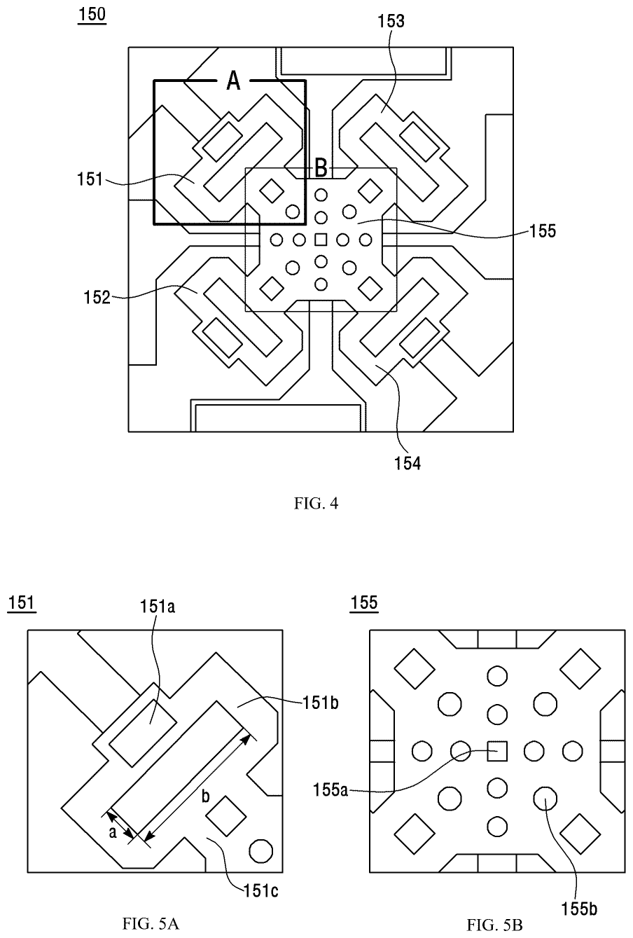

FIG. 4 is a plan view illustrating the switch body 150 included in the electromechanical switch 100 according to an embodiment of the present invention, FIG. 5A is an enlarged view illustrating portion A in FIG. 4, and FIG. 5B is an enlarged view illustrating portion B in FIG. 4.

Referring to FIGS. 4 and 5, the switch body 150 includes a first protruding part 151, a second protruding part 152, a third protruding part 153, a fourth protruding part 154, and a base part 155.

The first to fourth protruding parts 151, 152, 153, and 154 are connected to four side surfaces of the base part 155, respectively, and symmetrically arranged.

Referring to FIG. 5A, the first protruding part 151 includes a fixing part 151a, a spring part 151b, and a connection part 151c.

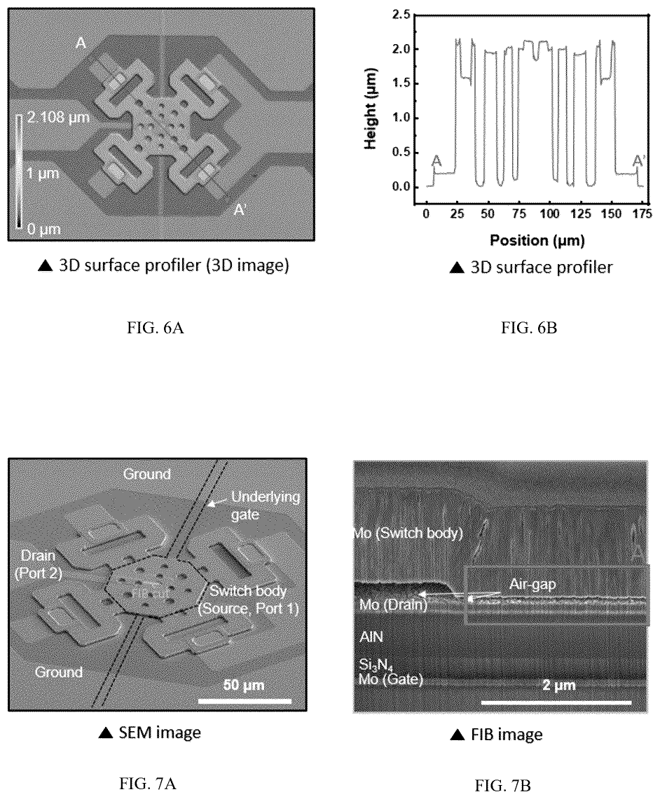

The fixing part 151a has a shape that protrudes downward and is disposed at one outermost side of the spring part 151b. More specifically, the fixing part 151a may have a shape pressed downward by a predetermined distance in comparison with the spring part 151b, the connection part 151c, and the base part 155. Referring to FIG. 6A and FIG. 6B, the shape of the fixing portion 151a may be inferred. With the above-described shape, the fixing part 151a may fix the switch body 150 onto the insulating layer 160 of the substrate 110.

The fixing part 151a may have a bottom surface that is in contact with the electrodes 140a and 140b disposed at both the ends of the third electrode 140. The fixing part 151a is brough into contact with the third electrode 140 to electrically connect the switch body 150 and the third electrode 140.

Due to the downward protruding shape of the fixing part 151a, a bottom surface of the rest portion of the switch body 150 except for the fixing part 151a may maintain a state that is not in contact with any component.

The spring part 151b may have a slot structure. The slot structure refers to a structure having a rectangular shape including a rectangular hole therein. In the rectangular hole, a horizontal length (first length, b in FIG. 5A) parallel to the base part 155 may be greater than a vertical length (second length, a in FIG. 5A) perpendicular to the base part 155.

The one outermost side of the spring part 151b may be connected to the fixing part 151a.

Each of two corners disposed adjacent to the base part 155 among four corners of the rectangular shape of the spring part 151b may have a chamfered shape instead of a sharp shape. However, the embodiment of the present invention is not limited thereto. For example, each of the two corners may have a gentle curved shape or an unchamfered shape.

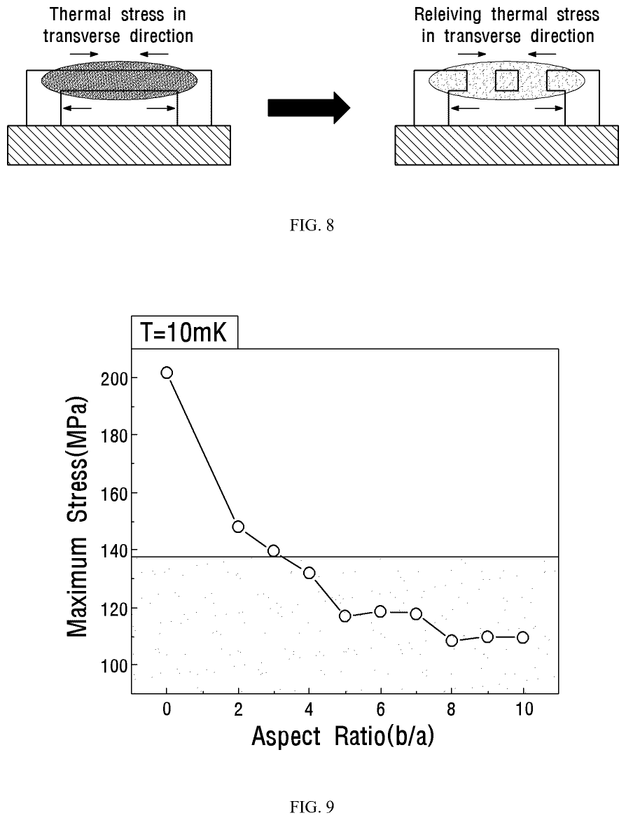

FIG. 8 is a view for comparing a typical electromechanical switch without the slot structure and the electromechanical switch 100 adopting the slot structure according to an embodiment of the present invention.

More specifically, FIG. 8 is a view for comparing the electromechanical switch 100 adopting the slot structure according to an embodiment of the present invention with a typical fixed-fixed beam type electromechanical switch among a cantilever type electromechanical switch and a fixed-fixed beam type electromechanical switch, which are representative shapes of the typical electromechanical switch.

The electromechanical switch 100 according to an embodiment of the present invention, by adopting the slot structure, may allow deformation in a transverse direction and effectively relieve thermal stress in the transverse direction, which is applied depending on temperature variations.

FIG. 9 is a graph showing results of a simulation (CoventorWare), which confirm that a maximum von Mises stress applied to the switch body 150 decreases as a ratio b/a of a first length b and a second length a of the slot structure increases in an ultra-low temperature (10 mK) environment. The maximum stress in FIG. 9 is calculated based on a condition when the switch body 150 is brought into contact with the second electrode 130 (Vg=50V).

Referring to FIG. 9, it may be known that the ratio b/a of the first length b and the second length a is required to be about 3 or more to design the maximum von Mises stress applied to the switch body 150 to be less than 137.5 MPa in the ultra-low temperature (10 mK) environment.

The connection part 151c is disposed between the base part 155 and the spring part 151b to structurally connect the base part 155 and the spring part 151b. The connection part 151c may have various shapes and be variously disposed between the base part 155 and the spring part 151b.

Since each of the second to fourth protruding parts 152, 153, and 154 is the same as the first protruding part 151 in terms of a structure, a detailed description thereof will be omitted.

Referring to FIG. 5B again, the base part 155 includes a contact part 155a and at least one etch hole 155b.

The base part 155 is disposed at a central point surrounded by the first to third electrodes 120, 130, and 140 and structurally connected to the first to fourth protruding parts 151, 152, 153, and 154.

The contact part 155a is disposed at an exact central portion of the base part 155. The contact part 155a may bring the second electrode 130 into contact with the switch body 150. The contact part 155a may have a downward protruding shape, more specifically, a shape pressed by a predetermined distance from an overall shape of the base part 155. Referring to FIG. 6A and FIG. 6B, the shape of the contact part 155a may be inferred.

Due to the downward protruding shape of the contact part 155a, the air-gap 170 disposed below a region in which the contact part 155a is disposed may have a thickness less than that of the air-gap 170 disposed on other areas. Thus, when a pull-in phenomenon occurs as electrostatic force greater than mechanical restoration force of the switch body 150 is applied between the first electrode 130 and the switch body 150, the switch body 150 and the second electrode 130 may have a predetermined contact area. Referring to FIG. 7B, region A is a region in which the contact part 155a is disposed and in which the switch body 150 is brought into contact with the second electrode 130 when the pull-in phenomenon occurs.

The base part 155 has at least one etch hole 155b. The etch hole 155b, as a path through which an etchant solution is permeated during a semiconductor manufacturing process, allows fast lateral etching. The etch hole 155b may have a circular shape, and a plurality of etch holes 155b may be symmetrically arranged. However, the embodiment of the present invention is not limited thereto. For example, the etch hole 155b may have various shapes, and the plurality of etch holes 155b may be variously arranged.

### Operation Principle of Electromechanical Switch

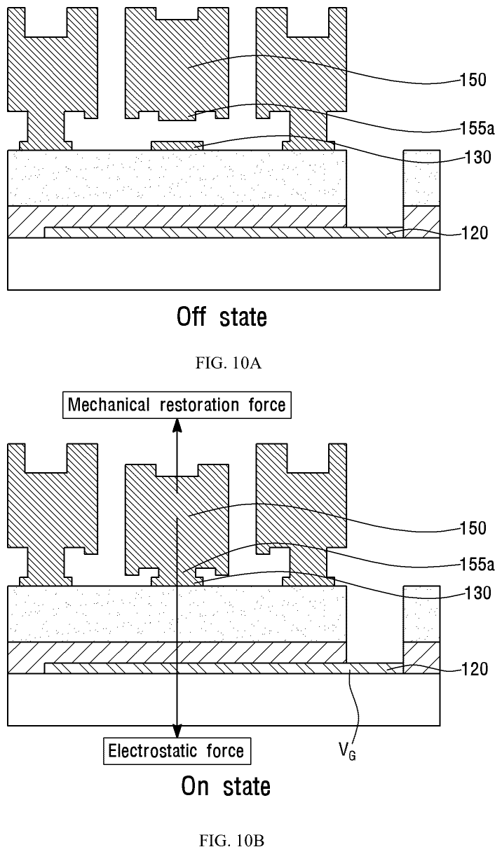

FIG. 10A and FIG. 10B are a view for explaining an operating principle of the electromechanical switch.

Referring to FIGS. 10A and 10B, the electromechanical switch according to an embodiment of the present invention may operate in two states that are an off-state and an on-state. FIG. 10A is a view illustrating the off state, and FIG. 10B is a view illustrating the on state.

The OFF state refers to a state in which the second electrode 130 is physically spaced apart from the switch body 150. Due to the feature in which the second electrode 130 is spaced apart from the switch body 150, a current flowing therebetween is close to zero. In particular, the air-gap 170 between the second electrode 130 and the switch body 150 fundamentally blocks a current flow caused by tunneling.

In the on state, the second electrode 130 is in physical and electrical contact with the switch body 150. A method for bringing the second electrode 130 into physical and electrical contact with the switch body 150 applies a predetermined voltage to the first electrode 120 to generate electrostatic force caused by a voltage difference between the first electrode 120 and the switch body 150. The second electrode 130 is brought into contact with the switch body 150 by the electrostatic force.

More specifically, when the voltage applied to the first electrode 120 increases so that the electrostatic force between the first electrode 130 and the switch body 150 is greater than the mechanical restoration force of the switch body 150, a displacement occurs in the switch body 150, and a pull-in phenomenon, in which the contact part 155a of the base part 155 of the switch body 150 is brought into contact with a top surface of the second electrode 130, occurs. Here, the mechanical contact between the contact part 155a and the second electrode 130 allows the second electrode 130 to be electrically connected to the switch body 150.

When a predetermined voltage applied to the first electrode 120 is removed in the on state, the electrostatic force between the first electrode 130 and the switch body 150 is removed, and the first electrode 130 and the switch body 150 are returned to the off state by the mechanical restoration force of the switch body 150.

### Simulation Result and Measurement Result

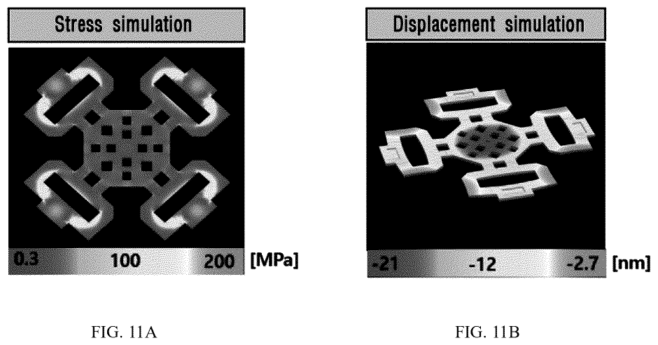

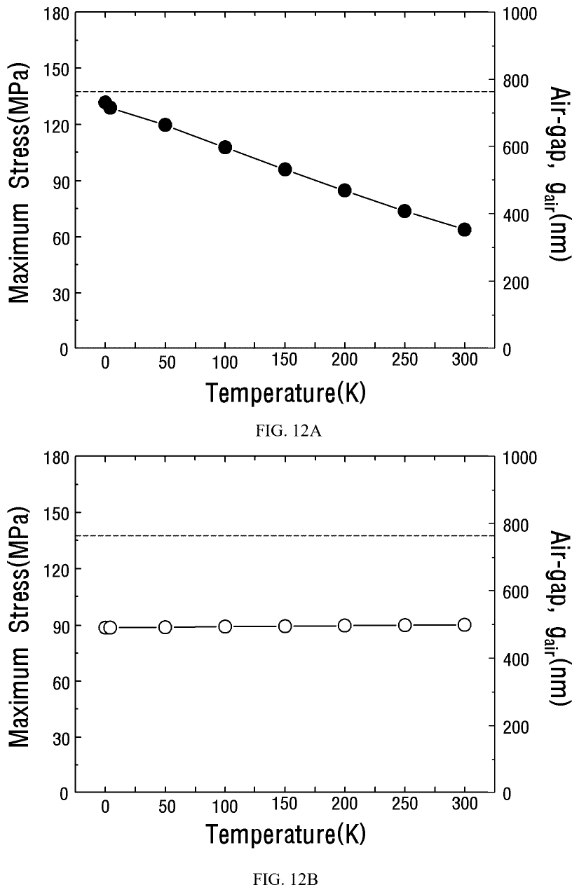

FIG. 11A and FIG. 11B are a view illustrating a result of a simulation that verifies operation stability of the electromechanical switch 100 at the ultra-low temperature according to an embodiment of the present invention, and FIG. 12A and FIG. 12B are a graph representing the result of the simulation of FIGS. 11A and 11B.

FIG. 11A is a view that visually represents the von Mises stress applied to the switch body 150 at a temperature of 10 mK. Referring to FIG. 11A and FIG. 12A, it may be known that the von Mises stress applied to the switch body 150 is greatest near the fixing part 151a and at a lowest temperature (10 mK).

FIG. 11B is a view that visually represents a displacement of the switch body 150 in a direction perpendicular to the substrate 110 at a temperature of 10 mK. Referring to FIG. 11B and FIG. 12B, at 10 mK, a displacement of the switch body 150 occurs in a range from −21 nm to −2.7 nm at the temperature of 10 mK. However, the displacement includes own displacement of the substrate 110 on which the switch body 150 is disposed, and the own displacement of the substrate 110 is equal to a displacement of the fixing part 151a that is a point at which the switch body 150 is brought into contact with the third electrode 140. Thus, a displacement of about −12 nm is generated in the substrate 110.

As a result, it may be known that a displacement of the air-gap 170 in the direction perpendicular to the substrate 110 is generated in a range from −9 nm to 9.3 nm at a temperature range from 10 mK to 300 K.

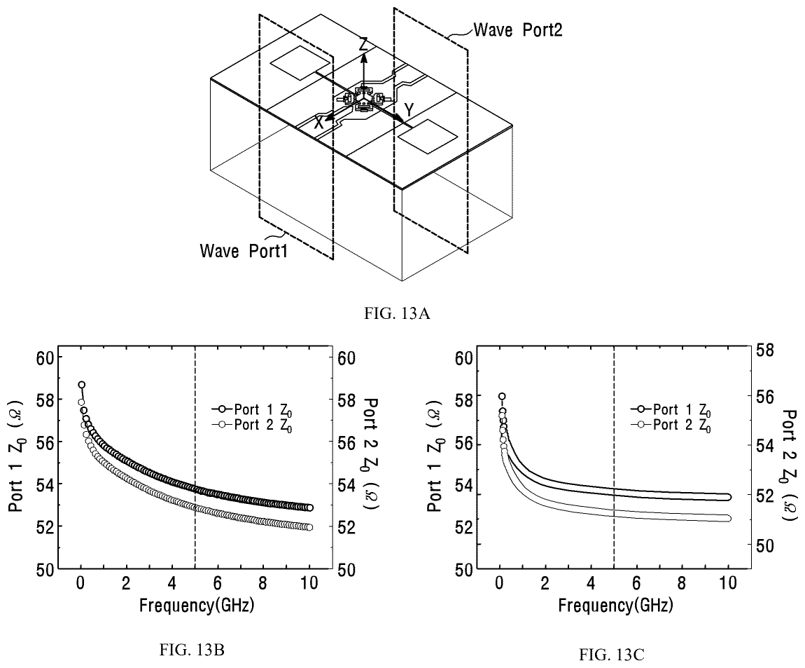

FIG. 13A, FIG. 13B and FIG. 13C are a view and a graph illustrating a result of a radio frequency (RF) simulation that verifies port impedance Zo of the electromechanical switch 100 according to an embodiment of the present invention.

FIG. 13A is an ANSYS HFSS simulation 3D view of the electromechanical switch 100 according to an embodiment of the present invention.

Referring to FIG. 13B and FIG. 13C, it may be known that impedance of an input port is approximately equal to impedance of an output port in both the on state and off state of the electromechanical switch 100 according to an embodiment of the present invention.

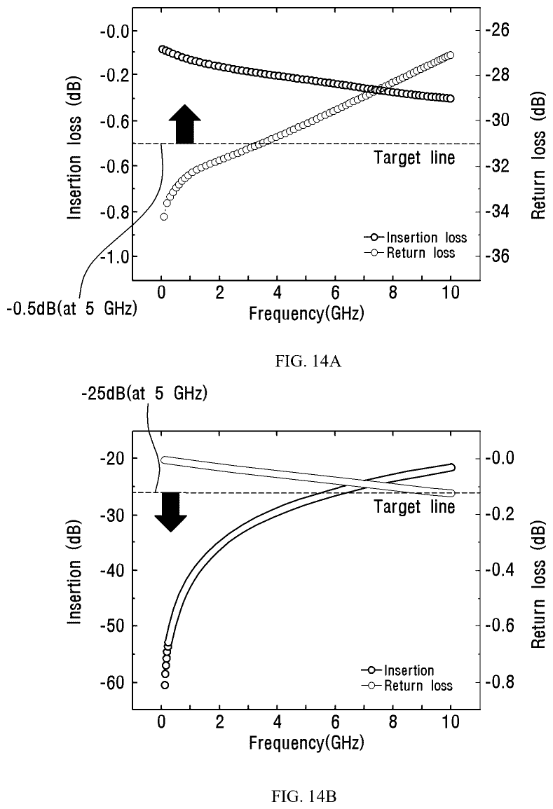

FIG. 14A and FIG. 14B are a graph illustrating a result of a RF simulation that extracts a S-parameter of the electromechanical switch 100 according to an embodiment of the present invention.

Referring to FIG. 14A, it may be known that the electromechanical switch 100 according to an embodiment of the present invention has an insertion loss of −0.22048 dB in the on state at a qubit center frequency of 5 GHz.

Referring to FIG. 14B, it may be known that the electromechanical switch 100 according to an embodiment of the present invention has an insertion loss of −27.5043 dB in the off state at the qubit center frequency of 5 GHz.

FIG. 15A and FIG. 15B are a graph representing a result obtained by measuring current-voltage characteristics at a temperature of 4.8 K of the electromechanical switch 100 according to an embodiment of the present invention.

FIG. 15B is an enlarged graph illustrating portion A in FIG. 15A.

Referring to FIG. 15A and FIG. 15B, it may be known that a voltage applied to the first electrode 120 is required to be about 35V or more to generate the pull-in phenomenon at a temperature of 4.8K in the electromechanical switch 100 according to an embodiment of the present invention.

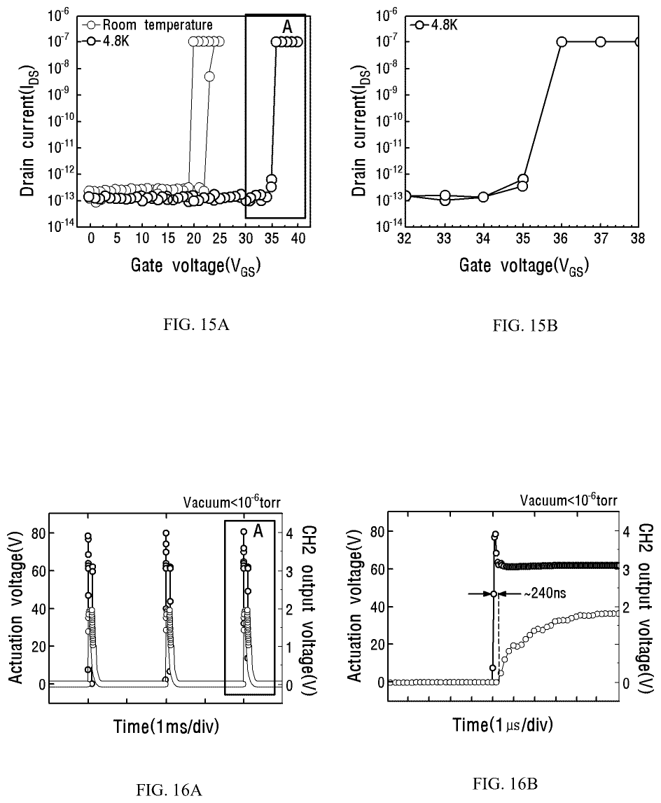

FIG. 16A and FIG. 16B are a graph representing a result obtained by measuring a switching time of the electromechanical switch 100 at a temperature of 4.8K according to an embodiment of the present invention.

FIG. 16B is an enlarged graph illustrating portion A in FIG. 16A.

Referring to FIG. 16A and FIG. 16B, it may be known that the switching time between the off state and the on state of the electromechanical switch 100 according to an embodiment of the present invention is less than 240 ns at a temperature of 4.8K.

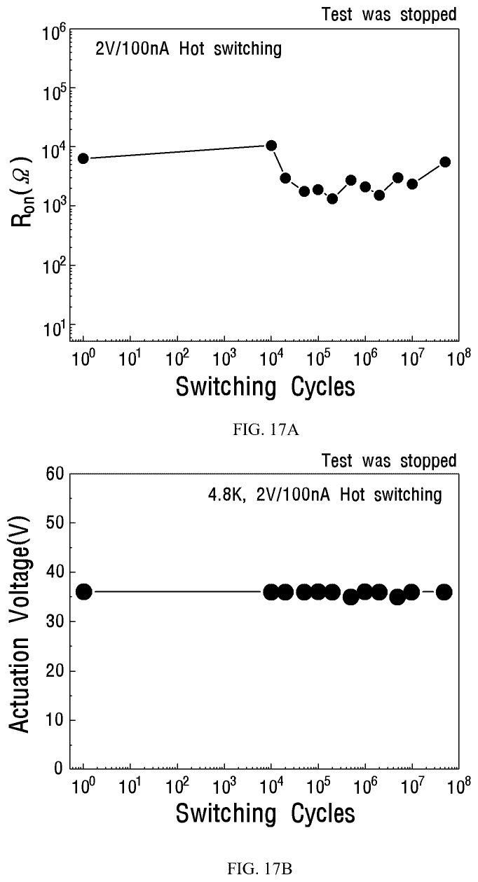

FIG. 17A and FIG. 17B are a graph representing a result obtained by measuring, at a temperature of 4.8K, a lifetime of the electromechanical switch 100 according to an embodiment of the present invention.

Referring to FIG. 17A and FIG. 17B, it may be known that the electromechanical switch 100 according to an embodiment of the present invention operates, at a temperature of 4.8K, 50 million cycles or more. However, this experiment is stop when liquid helium is completely used, and no critical damage is observed in terms of the on resistance and an actuation voltage. Thus, it is considered that the electromechanical switch 100 according to an embodiment of the present invention may operate more than 50 million cycles.

### Manufacturing Process

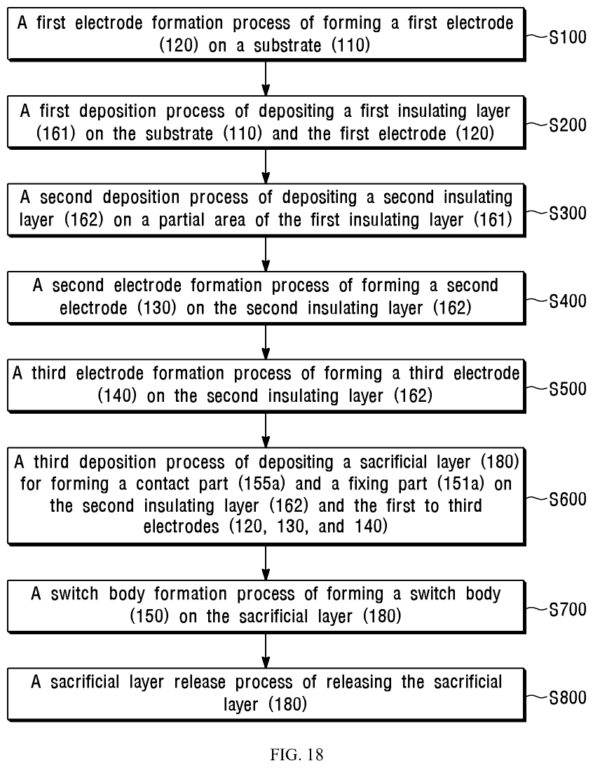

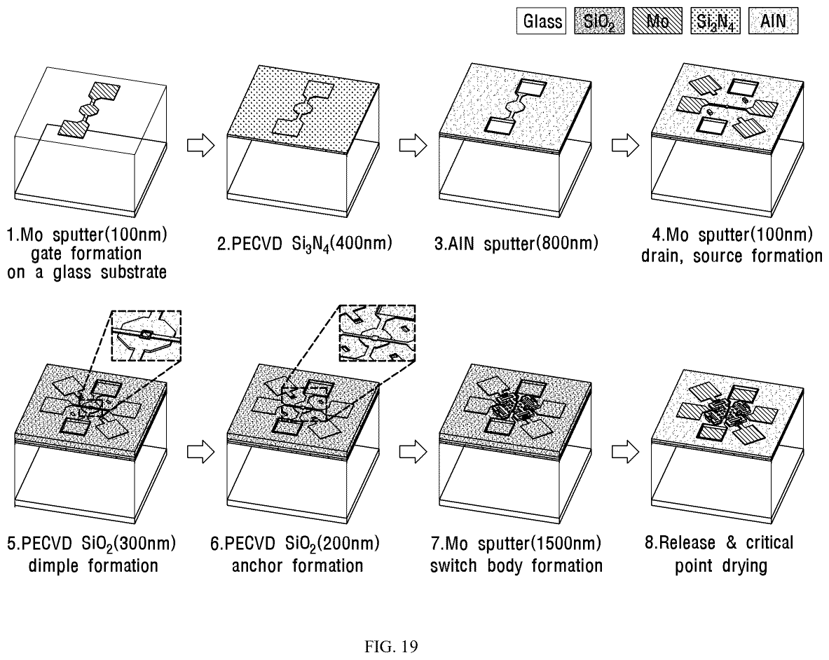

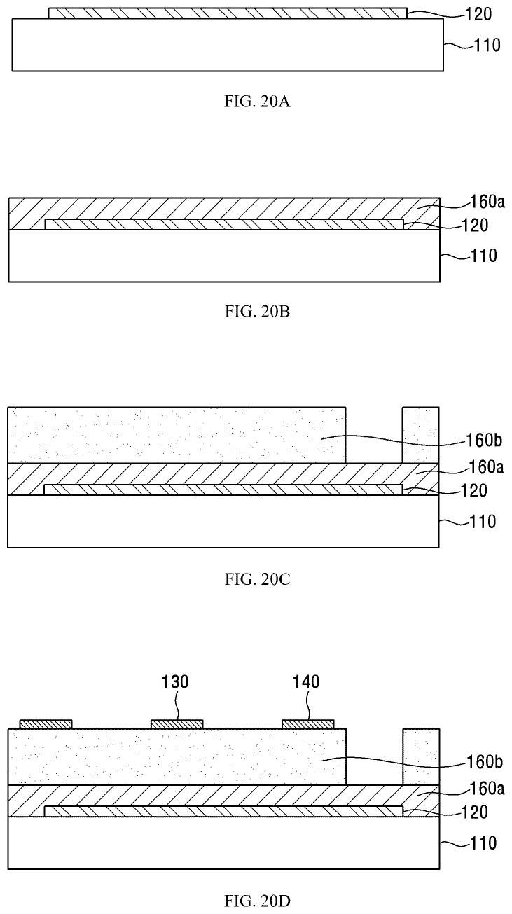

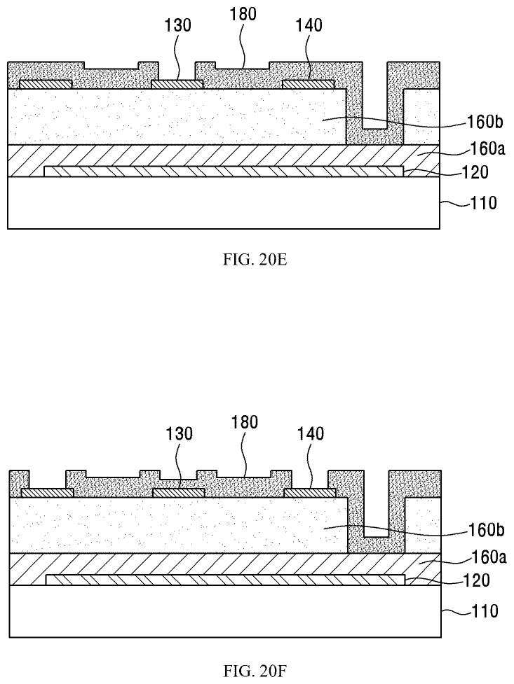

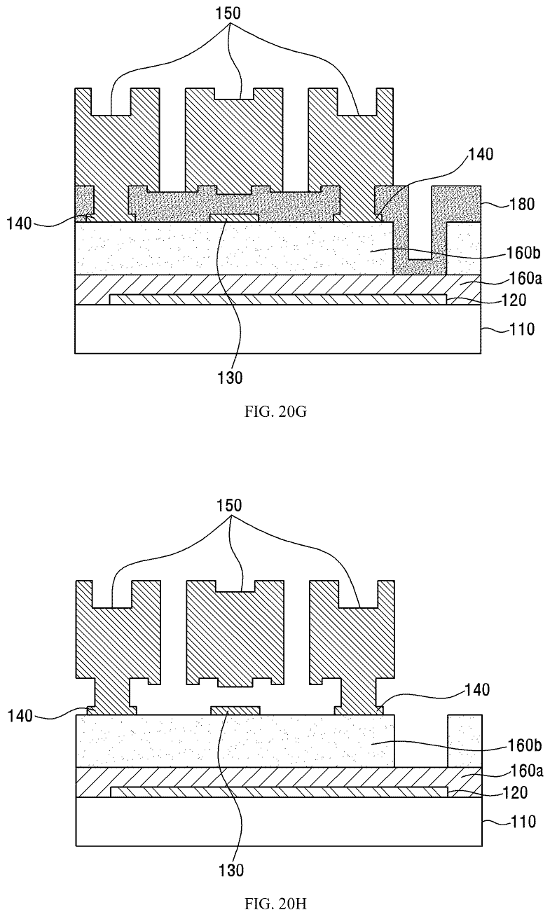

FIG. 18 is a flowchart representing a method for manufacturing the electromechanical switch 100 in FIG. 1, and FIG. 19 is a view for entire processes of the method for manufacturing the electromechanical switch 100 in FIG. 1. Also, FIGS. 20a to 20h are views for explaining, in detail, the method for manufacturing the electromechanical switch 100 in FIG. 19.

As illustrated in FIG. 18, the method for manufacturing the electromechanical switch 100 according to an embodiment of the present invention includes: a first electrode formation process S100, a first deposition process S200, second deposition process S300, a second electrode formation process S400, a third electrode formation process S500, a third deposition process S600, a switch body formation process S700, and a sacrificial layer release process S800.

FIG. 20A is a view for explaining the first electrode formation process S100 in FIG. 19. A first electrode 120 is formed on a substrate 110. The first electrode 120 may be made of molybdenum that is a superconducting material. Although the first electrode 120 may have a thickness of 100 nm, the embodiment of the present invention is not limited thereto.

For example, the thickness of the first electrode 120 may increase or decrease depending on a size of the electromechanical switch 100.

FIG. 20B is a view for explaining a first deposition process S200 in in FIG. 19. A first insulating layer 161 is deposited onto the substrate 110 and the first electrode 120. The first insulating layer 161 may be made of silicon nitride (Si₃N₄) and have a deposition thickness of 400 nm. However, the embodiment of the present invention is not limited thereto. For example, the thickness of the first insulating layer 161 may increase or decrease depending on the size of the electromechanical switch 100. Also, the first insulating layer 161 may be deposited in a plasma-enhanced chemical vapor deposition (PECVD).

FIG. 20C is a view for explaining the second deposition process S300 in FIG. 19. A second insulating layer 162 is deposited on a partial area of the first insulating layer 161. More particularly, the second insulating layer 162 may be deposited only on a partial area of the first insulating layer 161, except for an area in which the first electrode 120 is disposed. The second insulating layer 162 may be made of aluminum nitride (AlN) and have a deposition thickness of 800 nm. However, the embodiment of the present invention is not limited thereto. For example, the thickness of the second insulating layer 162 may increase or decrease depending on the size of the electromechanical switch 100. Also, the second insulating layer 162 may be deposited through sputtering.

FIG. 20D is a view for explaining the second electrode formation process S400 and the third electrode formation process S500 in FIG. 19. A second electrode 130 is formed on the second insulating layer 162. The second electrode 130 may be made of molybdenum that is a superconducting material. Also, the second electrode 130 may have a thickness of 100 nm. However, the embodiment of the present invention is not limited thereto. For example, the thickness of the second electrode 130 may increase or decrease depending on the size of the electromechanical switch 100.

Also, a third electrode 140 is formed on the second insulating layer 162. The third electrode 140 may be made of molybdenum that is a superconducting material. Also, the third electrode 140 may have a thickness of 100 nm. However, the embodiment of the present invention is not limited thereto. For example, the thickness of the third electrode 140 may increase or decrease depending on the size of the electromechanical switch 100.

FIGS. 20e and 20f are views for explaining the third deposition process S600 in FIG. 19.

A sacrificial layer 180 is deposited on the second insulating layer 162 and the first, second, and third electrodes 120, 130, and 140 to form a contact part 155a and a fixing part 151a. The sacrificial layer 180 may be made of silicon dioxide (SiO₂) and have a deposition thickness of 500 nm. However, the embodiment of the present invention is not limited thereto. For example, the thickness of the sacrificial layer 180 may increase or decrease depending on the size of the electromechanical switch 100. Also, the sacrificial layer 180 may be deposited through PECVD.

FIG. 20E is a view for explaining formation of the contact part 155a in the third deposition process S600 in FIG. 19. The contact part 155a may be formed on a switch body 150 by forming the sacrificial layer 180 only on an area except for a partial area of the second electrode 130.

FIG. 20F is a view for explaining formation of the fixing part 151a in the third deposition process S600 in FIG. 19. The fixing part 151a may be formed on the switch body 150 by forming the sacrificial layer 180 only on an area except for a partial area of the third electrode 140.

Thus, the sacrificial layer 180 may be deposited on the partial area of the second electrode 130 with a thin thickness and may not be deposited on the partial area of the third electrode 140. Accordingly, the air-gap 170 on the partial area of the second electrode 130 may have a thickness less than that of the air-gap 170 on other areas, and a top surface of the partial area of the third electrode 140 may be in contact with a bottom surface of the switch body 150.

FIG. 20G is a view for explaining the switch body formation process S700 in FIG. 19. The switch body 150 is formed on the sacrificial layer 180. The switch body 150 may be made of molybdenum that is a superconducting material. Although the switch body 150 may have a thickness of 1500 nm, the embodiment of the present disclosure is not limited thereto. For example, the thickness of the switch body 150 may increase or decrease depending on the size of the electromechanical switch 100. Here, the thickness of the switch body 150 may be greater than that of each of the first, second, and third electrodes 120, 130, and 140.

FIG. 20H is a view for explaining a sacrificial layer release process S800 in FIG. 19. The sacrificial layer 180 is released. More specifically, the sacrificial layer 180 is released by etching the sacrificial layer 180 using an etchant solution. Thus, the air-gap 170 may be formed between the second electrode 130 and the switch body 150. Also, the sacrificial layer release process S800 may be performed more quickly by at least one etch hole 155b included in the base part 155 of the switch body 150.

The electromechanical switch according to the embodiment of the present invention may operate with high reliability in the ultra-low temperature (10 to 100 mK) environment.

Also, the electromechanical switch according to the embodiment of the present invention has the low on-state resistance to process the RF signal.

Also, the thermal stress may be effectively relieved through the slot structure to operate with high reliability in the ultra-low temperature (10 to 100 mK) environment.

Also, the electromechanical switch according to the embodiment of the present invention has the low insertion loss by using the superconducting material, such as molybdenum, for the structure and/or the electrode. Furthermore, the electromechanical switch according to the embodiment of the present invention is suitable to be used for the qubit control and measurement circuit in the 10 mK environment in which the qubit is disposed. In particular, the spatio-temporal type circulator is proposed to solve the limitation of the large volume of the ferrite circulator that is currently used for qubit measurement and disposed at 10 mK of the quantum computer, and the electromechanical switch according to the embodiment of the present invention is expected to be highly suitable as the modulation element for the new type circulator.

Also, the electromechanical switch according to the embodiment of the present invention may be used in various applied fields that require the ultra-low temperature (10 to 100 mK) environment, such as the quantum computing, aerospace, and national defense.

Although embodiments have been described with reference to a number of illustrative embodiments thereof, it should be understood that numerous other modifications and embodiments may be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

### DESCRIPTION OF THE REFERENCE NUMERALS

100: Electromechanical switch
110: Substrate
120: First electrode
130: Second electrode
140: Third electrode
150: Switch body
151: First protruding part 152: Second protruding part 153: Third protruding part 154: Fourth protruding part
155: Base part
151a: Fixing part 151b: Spring part 151c: Connection part
155a: Contact part 155b: Etch hole
160: Insulating layer
161: First Insulating layer, 162: Second Insulating layer
170: Air-gap
180: Sacrificial layer
S100: First electrode formation process
S200: First deposition process
S300: Second deposition process
S400: Second electrode formation process
S500: Third electrode formation process
S600: Third deposition process
S700: Switch body formation process
S800: Sacrificial layer release process

What is claimed is:

1. An electromechanical switch comprising:
a substrate;
a first electrode disposed on the substrate;
a second electrode disposed on the substrate;
a third electrode disposed on the substrate; and
a switch body disposed at a central point surrounded by the first to third electrodes on the substrate,
wherein the second and third electrodes are spaced a predetermined distance from the first electrode.

2. The electromechanical switch of claim 1, wherein the switch body comprises:
a base part disposed on the central point;
a first protruding part;
a second protruding part;
a third protruding part; and
a fourth protruding part,
wherein the first to fourth protruding parts are connected to four side surfaces of the base part, respectively, and symmetrically arranged.

3. The electromechanical switch of claim 2, wherein the base part comprises a contact part configured to bring the second electrode into contact with the switch body, and
each of the first to fourth protruding parts comprises:
a fixing part configured to fix the switch body onto the substrate; and
a spring part that has a slot structure.

4. The electromechanical switch of claim 3, wherein the slot structure of the spring part has a first length that is greater than a second length.

5. The electromechanical switch of claim 1, wherein an air-gap is defined between the second electrode and the switch body.

6. The electromechanical switch of claim 5, wherein the air-gap has a displacement in a range from −9 nm to 9.3 nm in a direction perpendicular to the substrate at a temperature of 0.01K to 300K.

7. The electromechanical switch of claim 6, wherein when a predetermined voltage is applied to the first electrode, electrostatic force is generated between the first electrode and the switch body to bring the second electrode into contact with the switch body, and
the electrostatic force is greater than mechanical restoration force of the switch body.

8. The electromechanical switch of claim 7, wherein the electromechanical switch has:
an on state in which the second electrode is in contact with the switch body by the electrostatic force; and
an off state in which the second electrode is physically spaced apart from the switch body by the air-gap.

9. The electromechanical switch of claim 1, further comprising an insulating layer disposed between the first electrode and the second and third electrodes.

10. The electromechanical switch of claim 9, wherein the insulating layer comprises silicon nitride (Si₃N₄) and aluminum nitride (AlN).

11. The electromechanical switch of claim 1, wherein a maximum stress of the switch body is less than 137.5 MPa at a temperature of 0.01 K to 300 K.

12. The electromechanical switch of claim 1, wherein the switch body has a thickness greater than that of each of the first to third electrodes.

13. The electromechanical switch of claim 1, wherein each of the first to third electrodes and the switch body is made of a superconducting material.

14. The electromechanical switch of claim 13, wherein the superconducting material is molybdenum.

15. A method for manufacturing an electromechanical switch, the method comprising:
a first electrode formation process of forming a first electrode on a substrate;
a first deposition process of depositing a first insulating layer on the substrate and the first electrode;
a second deposition process of depositing a second insulating layer on a partial area of the first insulating layer;
a second electrode formation process of forming a second electrode on the second insulating layer;
a third electrode formation process of forming a third electrode on the second insulating layer;
a third deposition process of depositing a sacrificial layer for forming a contact part and a fixing part on the second insulating layer and the first to third electrodes;
a switch body formation process of forming a switch body on the sacrificial layer; and
a sacrificial layer release process of releasing the sacrificial layer.

16. The method of claim 15, wherein each of the first to third electrodes and the switch body is made of molybdenum.

17. The method of claim 15, wherein the first insulating layer is made of silicon nitride (Si₃N₄) and deposited through plasma-enhanced chemical vapor deposition.

18. The method of claim 15, wherein the second insulating layer is made of aluminum nitride (AlN) and deposited through sputtering.

19. The method of claim 15, wherein the sacrificial layer is made of silicon dioxide (SiO₂) and deposited through plasma-enhanced chemical vapor deposition.
